(19) United States
(12) Patent Application Publication
(10) Pub. No.: US 2025/0372390 A1
(43) Pub. Date: Dec. 4, 2025

(54) PLANARIZING METHOD, PLANARIZING SYSTEM, AND METHOD OF MANUFACTURING AN ARTICLE

(71) Applicant: CANON KABUSHIKI KAISHA, Tokyo (JP)

(72) Inventors: Takahiro Nakayama, Austin, TX (US); Timothy Brian Stachowiak, Austin, TX (US); Se-Hyuk Im, Austin, TX (US)

(21) Appl. No.: 18/679,149

(22) Filed: May 30, 2024

(51) Int. Cl. H01L 21/3105

(52) U.S. Cl. CPC H01L 21/31051

(57) ABSTRACT

A planarizing method comprises heating and bowing a superstrate held by a superstrate chuck by introducing a gas having a predetermined temperature into a chamber defined by the superstrate chuck and the superstrate, and heating and planarizing a formable material by contacting the heated bowed superstrate with the formable material, wherein the predetermined temperature of the gas is greater than a temperature of the formable material prior to contacting the heated bowed superstrate with the formable material.

### BACKGROUND

### Field of Art

The present disclosure relates to substrate processing, and more particularly, to a superstrate chuck assembly used in the planarization of surfaces in semiconductor fabrication and methods of manufacturing an article using that superstrate chuck assembly.

### Description of the Related Art

Planarization and imprinting techniques are useful in fabricating semiconductor devices. For example, the process for creating a semiconductor device includes repeatedly adding and removing material to and from a substrate. This process can produce a layered substrate with an irregular height variation (i.e., topography), and as more layers are added, the substrate height variation can increase. The height variation has a negative impact on the ability to add further layers to the layered substrate. Separately, semiconductor substrates (e.g., silicon wafers) themselves are not always perfectly flat and may include an initial surface height variation (i.e., topography). One method of addressing this issue is to planarize the substrate between layering steps and/or before layering steps. Various lithographic patterning methods benefit from patterning on a planar surface. In ArFi laser-based lithography, planarization reduces the impact of depth of focus (DOF) limitations, and improves critical dimension (CD), and critical dimension uniformity. In extreme ultraviolet lithography (EUV), planarization improves feature placement and reduces the impact of DOF limitations. In nanoimprint lithography (NIL) planarization improves feature filling and CD control after pattern transfer.

A planarization technique sometimes referred to as inkjet-based adaptive planarization (IAP) involves dispensing a variable drop pattern of polymerizable material between the substrate and a superstrate, where the drop pattern varies depending on the substrate topography. A superstrate is then brought into contact with the polymerizable material after which the material is cured (polymerized) on the substrate, and the superstrate removed.

The curing is typically performed at room temperature, for example 20° C. The cured layer is then baked to form a baked layer. The thickness of the baked layer is thinner than the thickness of the photocurable composition. The thickness change reduces the planarization performance of the baked layer. The resulting surface of the baked layer may have a non-uniform topography that has some areas that are at a locally lower elevation and other areas that are at a locally higher elevation. A planarization layer having no elevational difference or at least less elevational differences across such surface is desired.

### SUMMARY

A planarizing method comprises heating and bowing a superstrate held by a superstrate chuck by introducing a gas having a predetermined temperature into a chamber defined by the superstrate chuck and the superstrate, and heating and planarizing a formable material by contacting the heated bowed superstrate with the formable material, wherein the predetermined temperature of the gas is greater than a temperature of the formable material prior to contacting the heated bowed superstrate with the formable material.

A planarization system comprises a superstrate chuck configured to hold a superstrate, a chamber at least partially defined by the superstrate chuck, and a gas source in communication with the chamber and configured to introduce a gas having a predetermined temperature into the chamber, wherein the predetermined temperature of the gas is 70° C. to 120° C.

A method of manufacturing an article comprises dispensing a formable material on a substrate, heating and bowing a superstrate held by a superstrate chuck by introducing a gas having a predetermined temperature into a chamber defined by the superstrate chuck and the superstrate, heating and planarizing the formable material by contacting the heated bowed superstrate with the formable material, thereby forming a film of the formable material between the superstrate and the substrate, curing the film of the formable material to form a cured layer between the plate (superstrate) and the substrate, and processing the cured formable material to make the article, wherein the predetermined temperature of the gas is greater than a temperature of the formable material prior to contacting the heated bowed superstrate with the formable material.

These and other objects, features, and advantages of the present disclosure will become apparent upon reading the following detailed description of exemplary embodiments of the present disclosure, when taken in conjunction with the appended drawings, and provided claims.

### BRIEF DESCRIPTION OF DRAWINGS

So that features and advantages of the present disclosure can be understood in detail, a more particular description of embodiments of the disclosure may be had by reference to the embodiments illustrated in the appended drawings. It is to be noted, however, that the appended drawings only illustrate typical embodiments of the disclosure and are therefore not to be considered limiting of its scope, for the disclosure may admit to other equally effective embodiments.

FIG. 1 is a schematic diagram illustrating an example planarization system in accordance with an aspect of the present disclosure.

FIGS. 2A to 2C illustrate a schematic cross section of an example planarization process in accordance aspect of the present disclosure.

FIG. 3A shows a bottom view of an example superstrate chuck assembly in accordance with a first embodiment of the present disclosure.

FIG. 3B shows a top view of the superstrate chuck assembly of FIG. 3A.

FIG. 3C shows a cross section taken along line 3C-3C of FIG. 3B.

FIG. 3D shows an enlarged portion 3D of FIG. 3C.

FIG. 3E shows a perspective view of the enlarged portion 3D of FIG. 3C.

FIG. 4 shows an exploded view of the superstrate chuck assembly of FIGS. 3A to 3E.

FIG. 5 shows a flow chart of an example planarization method in accordance with aspect of the present disclosure.

FIGS. 6A to 6L show a series of schematic cross sections of the planarization method of FIG. 5, in accordance with an example embodiment.

FIGS. 7A to 7H, are valve and temperature timing charts indicating the temperature of various components at different moments in the planarization method relative to an initial temperature at the start of the planarization method.

While the subject disclosure will now be described in detail with reference to the figures, it is done so in connection with the illustrative exemplary embodiments. It is intended that changes and modifications can be made to the described exemplary embodiments without departing from the true scope and spirit of the subject disclosure as defined by the appended claims.

### DETAILED DESCRIPTION

### Planarization System

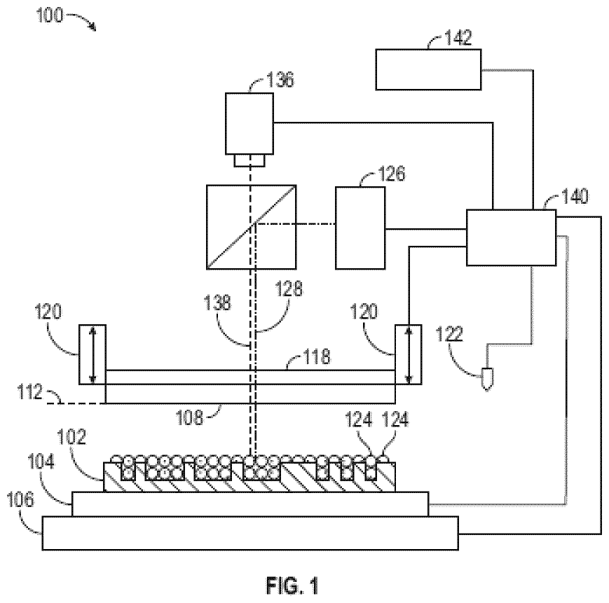

FIG. 1 illustrates an example system for shaping a surface in accordance with an aspect of the present disclosure. The system for shaping a surface may be, for example, a planarization system or an imprint system. The example embodiment described herein is a planarization system 100. However, the concepts are also applicable to an imprint system. Thus, while the terminology throughout this disclosure is primarily focused on planarization, it should be understood that the disclosure is also applicable to the corresponding terminology of an imprint context.

The planarization system 100 is used to planarize a film on a substrate 102. In the case of an imprint system, the imprint system is used to form a pattern on the film on the substrate. The substrate 102 may be coupled to a substrate chuck 104. The substrate chuck 104 may be but is not limited to a vacuum chuck, pin-type chuck, groove-type chuck, electrostatic chuck, electromagnetic chuck, and/or the like.

The substrate 102 and the substrate chuck 104 may be further supported by a substrate positioning stage 106. The substrate positioning stage 106 may provide translational and/or rotational motion along one or more of the x-, y-, z-, θ-, Ψ-, and φ-axes. The substrate positioning stage 106, the substrate 102, and the substrate chuck 104 may also be positioned on a base (not shown). The substrate positioning stage may be a part of a positioning system. The substrate positioning stage 106 may include a passive cooling system and/or an active cooling system.

Spaced apart from the substrate 102 is a superstrate 108 (also referred herein as a plate) having a working surface 112 facing substrate 102. The superstrate 108 may be formed from materials including, but not limited to, fused silica, quartz, silicon, organic polymers, siloxane polymers, borosilicate glass, fluorocarbon polymers, metal, hardened sapphire, and/or the like. In an embodiment the superstrate is readily transparent to UV light. The working surface 112 is generally of the same areal size or slightly smaller as the surface of the superstrate 108. The working surface 112 may include one or more layers of material that are different from the bulk material of the superstrate 108. The one more layers may have gas transport properties, surface release properties, and surface topography properties that allow the planarization system 100 to form a planarized layer with a surface variation that is on the nanometer scale. Examples of such superstrates are described in US patent publication Nos. 2019-0227437, 2020-0286740, and 2023-0167017 which are hereby incorporated by reference in their entirety.

The superstrate 108 may be coupled to or retained by a superstrate chuck assembly 118 (also referred herein as a superstrate chuck assembly), which is discussed in more detail below. The superstrate chuck assembly 118 may be coupled to a planarization head 120 which is a part of the positioning system. In the context of an imprint system, the planarization head may be referred to as an imprint head. The planarization head 120 may be movably coupled to a bridge. The planarization head 120 may include one or more actuators such as voice coil motors, piezoelectric motors, linear motor, nut and screw motor, etc., which are configured to move the superstrate chuck assembly 118 relative to the substrate 102 in at least the z-axis direction, and potentially other directions (e.g., x-, y-, θ-, Ψ-, and φ-axis).

The planarization system 100 may further comprise a fluid dispenser 122. The fluid dispenser 122 may also be movably coupled to the bridge. In an embodiment, the fluid dispenser 122 and the planarization head 120 share one or more of all positioning components. In an alternative embodiment, the fluid dispenser 122 and the planarization head move independently from each other. The fluid dispenser 122 may be used to deposit droplets of liquid formable material 124 (e.g., a photocurable polymerizable material) onto the substrate 102 with the volume of deposited material varying over the area of the substrate 102 based on at least in part upon its topography profile. Different fluid dispensers 122 may use different technologies to dispense formable material 124. When the formable material 124 is jettable, ink jet type dispensers may be used to dispense the formable material. For example, thermal ink jetting, microelectromechanical systems (MEMS) based ink jetting, valve jet, and piezoelectric ink jetting are common techniques for dispensing jettable liquids.

The planarization system 100 may further comprise a curing system that includes a radiation source 126 that directs actinic energy, for example, UV radiation, along an exposure path 128. The planarization head 120 and the substrate positioning stage 106 may be configured to position the superstrate 108 and the substrate 102 in superimposition with the exposure path 128. The radiation source 126 sends the actinic energy along the exposure path 128 after the superstrate 108 has contacted the formable material 124. FIG. 1 shows the exposure path 128 when the superstrate 108 is not in contact with the formable material 124. This is done for illustrative purposes so that the relative position of the individual components can be easily identified. An individual skilled in the art would understand that exposure path 128 would not substantially change when the superstrate 108 is brought into contact with the formable material 124.

The planarization system 100 may further comprise a camera 136 positioned to view the spread of formable material 124 as the superstrate 108 contacts the formable material 124 during the planarization process. FIG. 1 illustrates an optical axis 138 of the field camera's imaging field. As illustrated in FIG. 1, the planarization system 100 may include one or more optical components (dichroic mirrors, beam combiners, prisms, lenses, mirrors, etc.) which combine the actinic radiation with light to be detected by the camera 136. The camera 136 may include one or more of a CCD, a sensor array, a line camera, and a photodetector which are configured to gather light at a wavelength that shows a contrast between regions underneath the superstrate 108 and in contact with the formable material 124 and regions underneath the superstrate 108 but not in contact with the formable material 124. The camera 136 may be configured to provide images of the spread of formable material 124 underneath the superstrate 108, and/or the separation of the superstrate 108 from the planarized layer 146. The camera 136 may also be configured to measure interference fringes, which change as the formable material 124 spreads between the gap between the working surface 112 and the substrate surface. The camera 136 may also be configured to measure interference fringes due to reflections from the working surface 112 and substrate surface.

The planarization system 100 may be regulated, controlled, and/or directed by one or more processors 140 (controller) in communication with one or more components and/or subsystems such as the substrate chuck 104, the substrate positioning stage 106, the superstrate chuck assembly 118, the planarization head 120, the fluid dispenser 122, the radiation source 126, and/or the camera 136. The processor 140 may operate based on instructions in a computer readable program stored in a non-transitory computer memory 142. The processor 140 may be or include one or more of a CPU, MPU, GPU, ASIC, FPGA, DSP, and a general-purpose computer. The processor 140 may be a purpose-built controller or may be a general-purpose computing device that is adapted to be a controller. Examples of a non-transitory computer readable memory include but are not limited to RAM, ROM, CD, DVD, Blu-Ray, hard drive, networked attached storage (NAS), an intranet connected non-transitory computer readable storage device, and an internet connected non-transitory computer readable storage device. All of the method steps described herein may be executed by the processor 140.

In operation, either the planarization head 120, the substrate positioning stage 106, or both vary a distance between the superstrate 108 and the substrate 102 to define a desired space (a bounded physical extent in three dimensions) that is filled with the formable material 124. For example, the planarization head 120 may be moved toward the substrate and apply a force to the superstrate 108 such that the superstrate contacts and spreads droplets of the formable material 124 as further detailed herein.

### Planarization Process

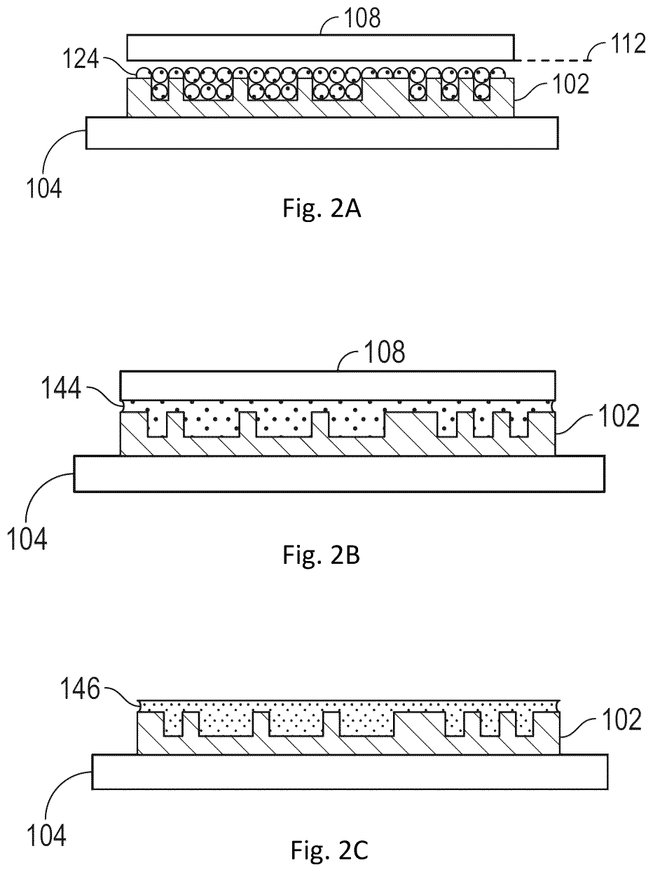

The planarization process includes steps which are shown schematically in FIGS. 2A-2C. As illustrated in FIG. 2A, the formable material 124 is dispensed in the form of droplets onto the substrate 102. As discussed previously, the substrate surface has some topography which may be known based on previous processing operations or may be measured using a profilometer, AFM, SEM, or an optical surface profiler based on optical interference effect like Zygo NewView 8200. The local volume density of the deposited formable material 124 is varied depending on the substrate topography. The superstrate 108 is then positioned in contact with the formable material 124.

FIG. 2B illustrates a post-contact step after the superstrate 108 has been brought into full contact with the formable material 124 but before a polymerization process starts. As the superstrate 108 contacts the formable material 124, the droplets merge to form a formable material film 144 that fills the space between the superstrate 108 and the substrate 102. Preferably, the filling process happens in a uniform manner without any air or gas bubbles being trapped between the superstrate 108 and the substrate 102 in order to minimize non-fill defects. The polymerization process or curing of the formable material 124 may be initiated with actinic radiation (e.g., UV radiation). For example, radiation source 126 of FIG. 1 can provide the actinic radiation causing formable material film 144 to cure, solidify, and/or cross-link, defining a cured planarized layer 146 on the substrate 102. Alternatively, curing of the formable material film 144 can also be initiated by using heat, pressure, chemical reaction, other types of radiation, or any combination of these. Once cured, a planarized layer 146 is formed, and the superstrate 108 can be separated therefrom. FIG. 2C illustrates the cured planarized layer 146 on the substrate 102 after separation of the superstrate 108. The substrate 102 and the planarized layer 146 may then be subjected to additional known steps and processes for device (article) fabrication, including, for example, baking, patterning, curing, oxidation, layer formation, deposition, doping, planarization, etching, formable material removal, dicing, bonding, and packaging, and the like. The substrate may be processed to produce a plurality of articles (devices).

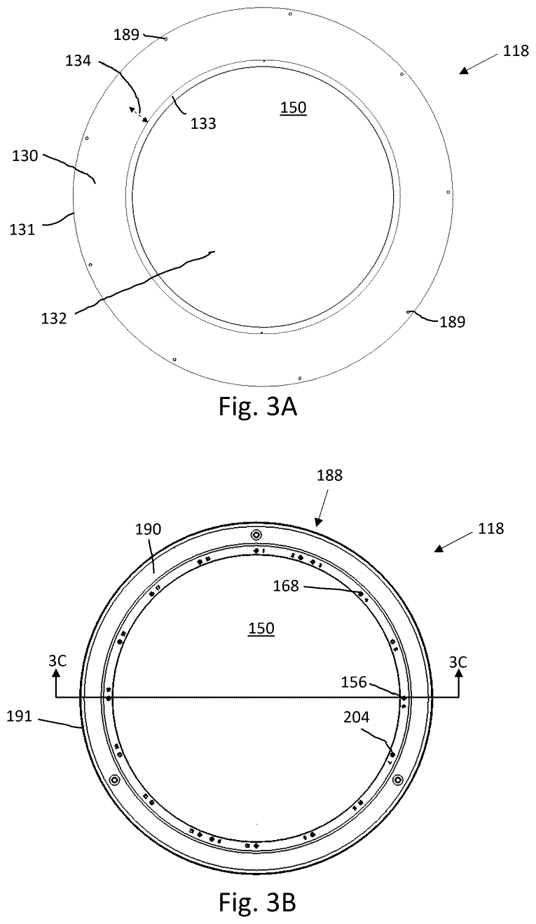

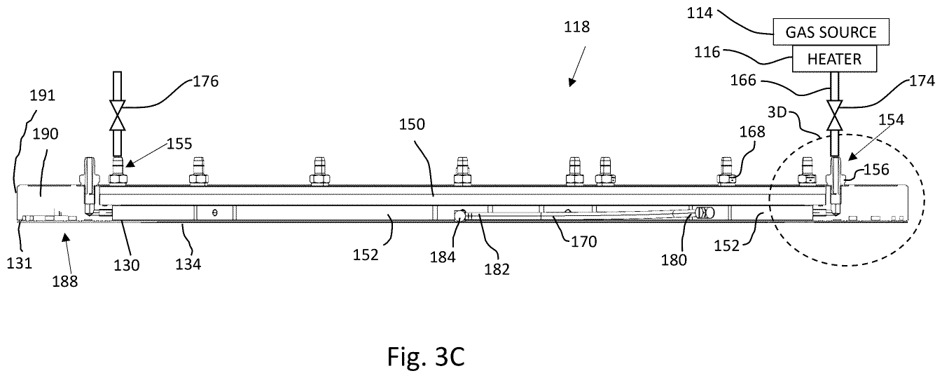

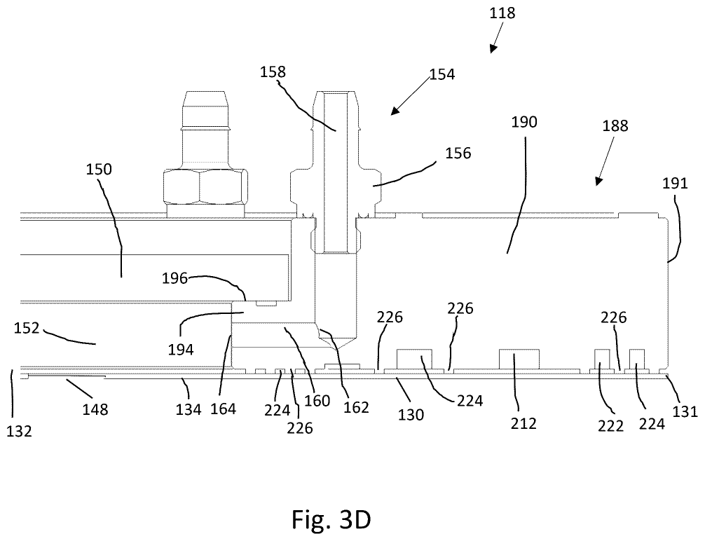

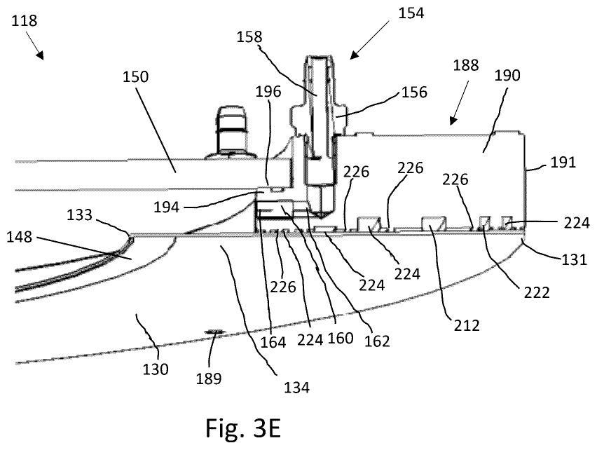

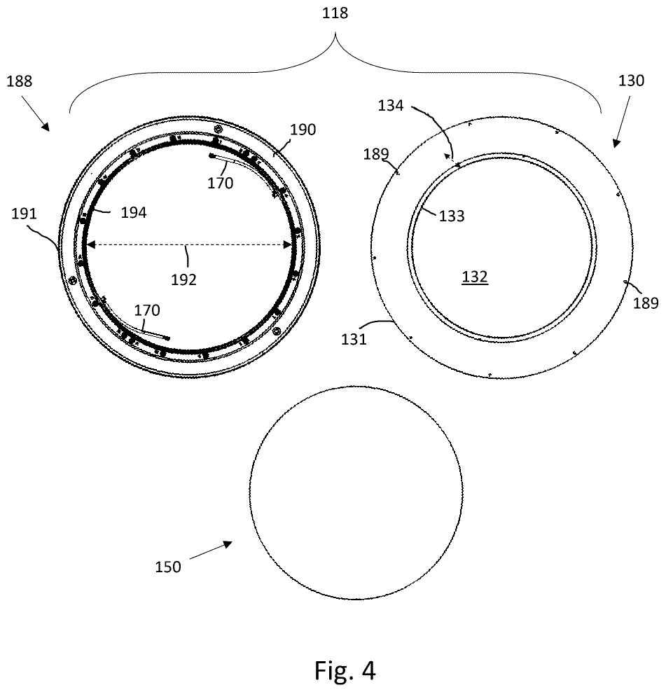

An example superstrate chuck assembly 118 is shown in FIGS. 3A to 4 in accordance with a first example embodiment. FIG. 3A shows a bottom view of the superstrate chuck assembly 118. FIG. 3B shows a top view of the superstrate chuck assembly 118. FIG. 3C shows a cross section taken along line 3C-3C of FIG. 3B. FIG. 3D shows an enlarged portion 3D of FIG. 3C. FIG. 3E shows a perspective view of the enlarged portion 3D of FIG. 3C.

As shown in FIGS. 3A to 3E, the superstrate chuck assembly 118 may include a superstrate holding member 130 preferably having a ring shape. The superstrate holding member 130 may include a flexible portion 134. The size of the flexible portion 134 of the superstrate holding member 130 may be varied while performing the planarization process, as discussed in U.S. Pat. No. 11,728,203, issued Aug. 15, 2023, which is hereby incorporated by reference herein in its entirety.

The superstrate holding member 130 may further include a cavity 148 (FIGS. 3D, 3E) configured to hold a portion of the superstrate 108 to the flexible portion 134 of the superstrate holding member 130. The cavity 148 may be an annular cavity concentrically surrounding the central opening 132. The cavity 148 may be located adjacent the inner edge 133 of the superstrate holding member 130. The cavity 148 may be formed as a recessed portion in the flexible portion 134.

The superstrate chuck assembly 118 may further include a light-transmitting member 150 that covers the central opening 132 of the superstrate holding member 130. In one example embodiment, the light-transmitting member 150 is preferably transparent to UV light with high UV light transmissivity. That is, the material composition of the light-transmitting 150 member may be selected such that UV light used to cure the formable material passes through the light-transmitting member 150. In one example embodiment when the light-transmitting member 150 transmits UV light, the light-transmitting member may be composed of a material that transmits greater than 80% of light having a wavelength of 310-700 nm (i.e., UV light and visible light), e.g., sapphire, fused silica). In another example embodiment, the light-transmitting member need not be transparent with respect to UV light. When the light-transmitting member need not be transparent with respect to UV light, the light-transmitting member may be composed of a material that transmits greater than 80% of light having a wavelength of 400-700 nm (i.e., visible light), e.g., glass, borosilicate. That is, in the case when it is not necessary to transmit UV light, the light-transmitting member 150 should still transmit visible light. The light-transmitting member 150 may be composed of a material that transmits greater than 50% of the wavelength of the light that the camera 136 uses to monitor the shape of the superstrate while the superstrate 108 is held by the superstrate chuck assembly 118 during the planarizing method.

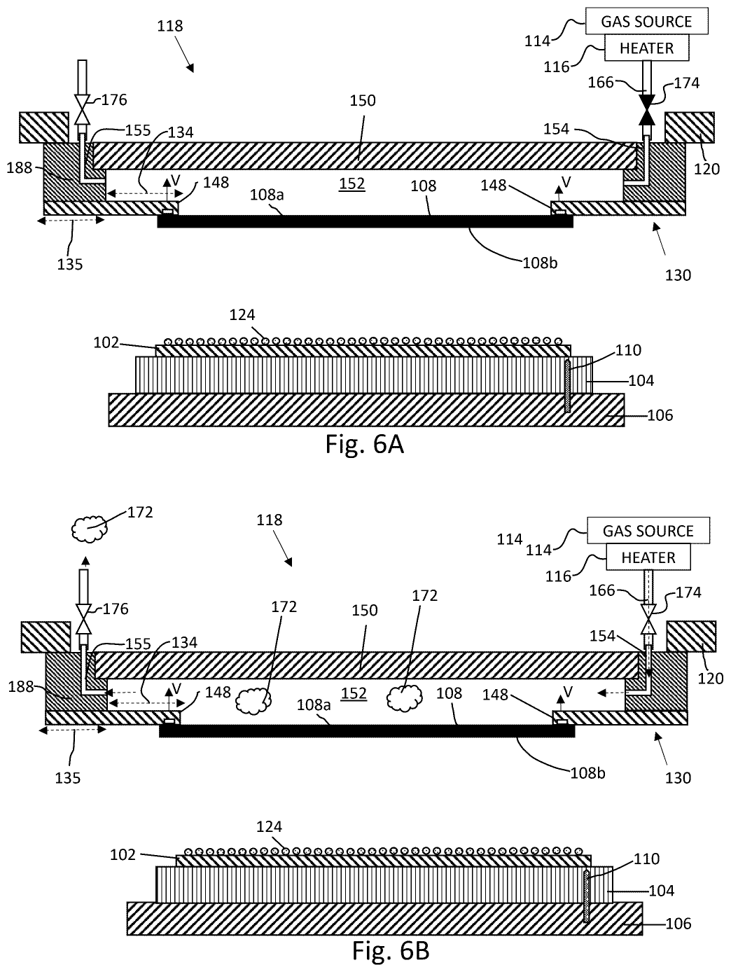

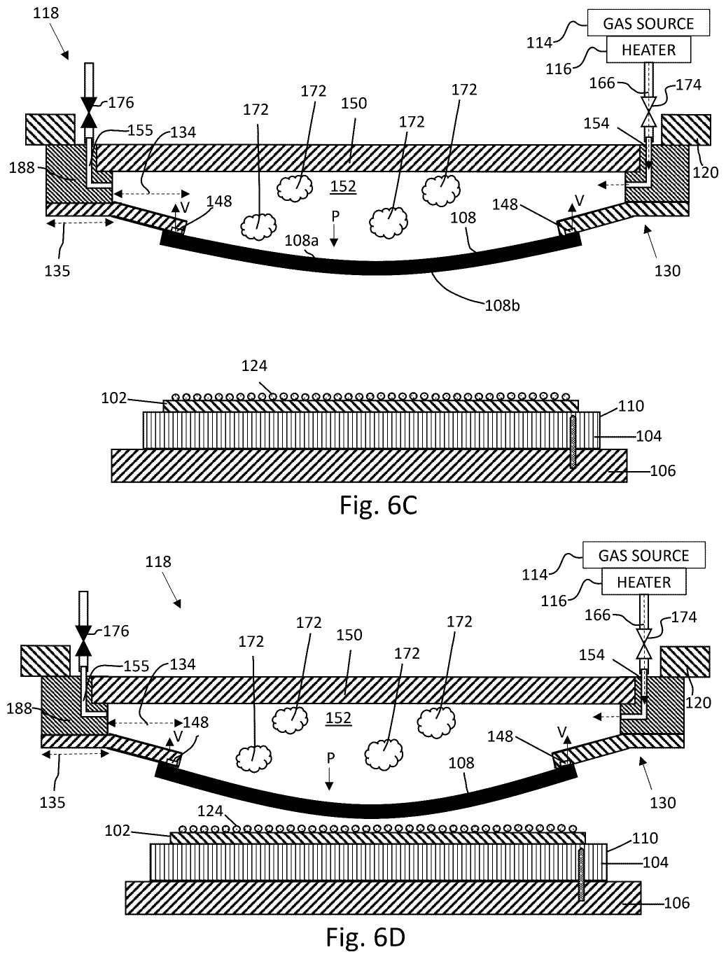

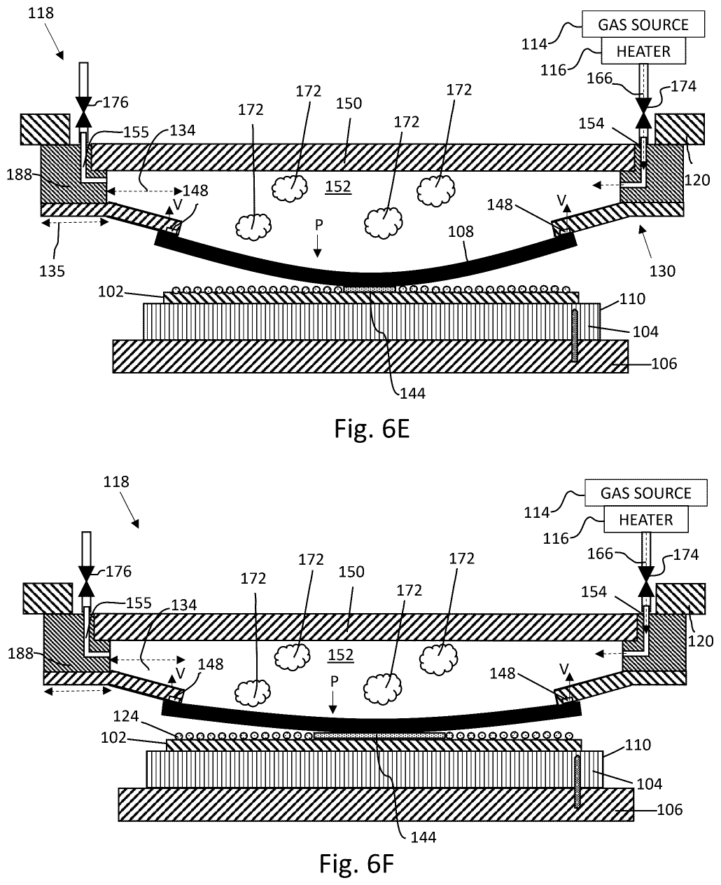

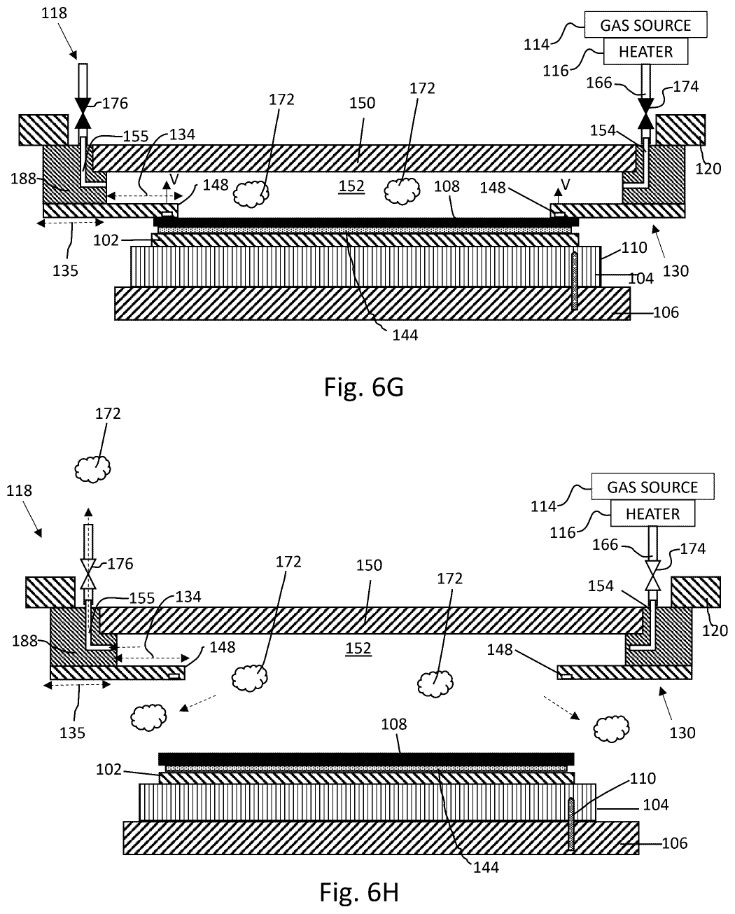

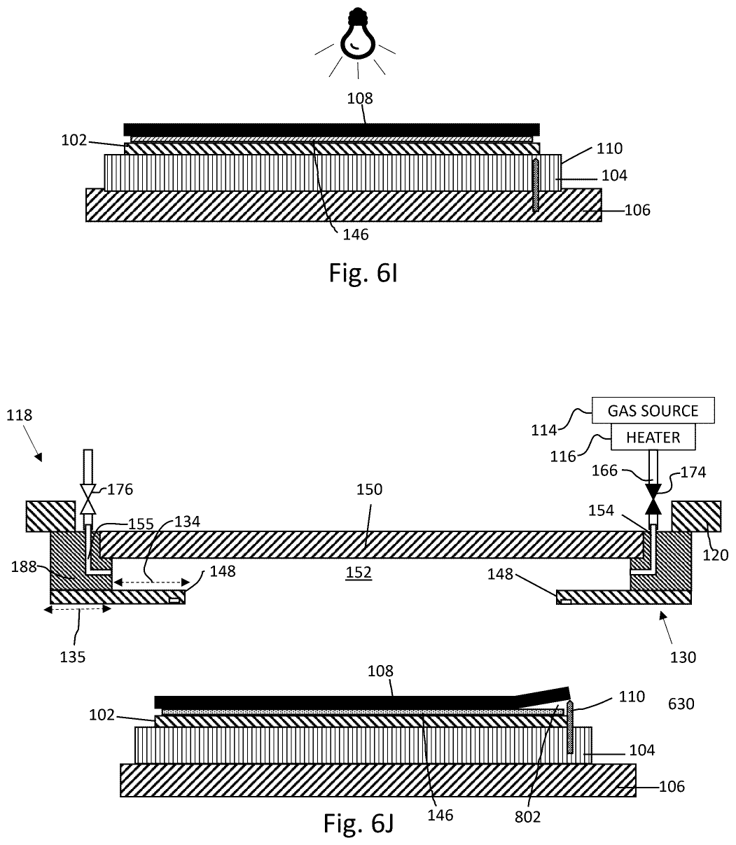

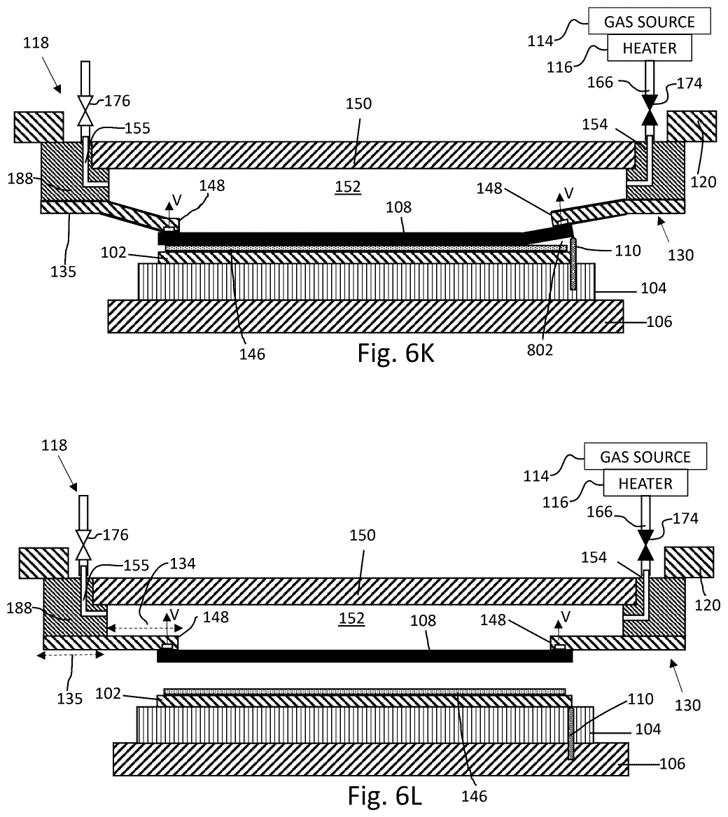

As best seen in FIGS. 3C, 3D, 3E, and FIGS. 6A to 6G, the superstrate chuck assembly 118 may include a chamber 152 defined by the superstrate holding member 130, the superstrate 108, and the light-transmitting member 150. More particularly, a bottom surface of the light-transmitting member 150, an upper surface and outer edge of the superstrate 108, and an upper surface of the superstrate holding member 130, being spaced apart, together define the chamber 152. The chamber 152 may be further defined by the inner side wall of a rigid member 188, discussed below. As also best seen in FIGS. 3C, 3D, 3E, the superstrate chuck assembly 118 may further include a fluid path 154 in communication with the chamber 152 for pressurizing the chamber 152 and for providing heat to the superstrate 108. As used herein, pressurizing includes both positive pressure and negative pressure.

The fluid path 154 can also be used to open the chamber 152 to atmosphere. The fluid path 154 may include components that together allow the chamber 152 to be selectively positively or negatively pressurized. In the illustrated example, the fluid path 154 includes a first port 156 connectable with a gas source 114. The gas in the gas source 114 may be heated using a heater 116. The heater heats the gas to a predetermined temperature, as discussed in more detail below. The gas of the gas source 114 may be clean dry air, nitrogen, helium, neon, argon, or mixtures thereof. The heater 116 may be a gas line heater, a gas heater tank, an electrical heating element, a cloth type heater, or other systems for heating a gas. The introduction of gas from the gas source 114 into the chamber 152 pressurizes the chamber 152 when the superstrate 108 is held by the superstrate chuck assembly 118 may be controlled by a gas supply valve 174 which is controlled by the processors 140. Because the gas being introduced into the chamber 152 has already been heated to a predetermined temperature via the heater 116, the introduction of the gas into the chamber 152 also heats the superstrate 108.

The first port 156 may be connected to the pressurizing source/gas source 114 via a gas supply line 166, for example. The first port 156 includes a first passage 158 in communication with the gas supply line 166 and in communication with a second passage 160. A first end 162 of the second passage 160 connects with the first passage 158 and a second end 164 of the second passage 160 connects to the chamber 152. Thus, when the first port 156 is connected to the pressurizing source/gas source 114, positive pressure can be applied to pressurize the chamber 152 via the first fluid path 154. Furthermore, because the gas of the gas source 114 is heated to a predetermined temperature, the gas used to pressurize the chamber 152 also heats the superstrate 108. One or more additional fluid paths may be implemented that have the same structure as the above-discussed fluid path 154. For example, as best seen in FIG. 3C, an additional fluid path 155 having the same structure as the fluid path 154 may be located at a position diametrically opposing the fluid path 154. The additional fluid path 155 may serve has an outlet flow path for the gas being supplied by the gas source 114 and may include a gas outlet valve 176 that is controlled by the processors 140. That is, the gas may enter the chamber 152 and then flow out of the additional fluid path 155 when the gas outlet valve 176 is open. Accordingly, the fluid path 154 may be referred to as a first fluid path or an inlet fluid path, while the additional fluid path 155 may be referred to as a second fluid path or an outlet fluid path. In the case where there is only one fluid path 154, then it would be both the inlet and outlet fluid path.

The superstrate may be held by the flexible portion 134 by reducing pressure in the cavity 148. One manner of reducing pressure in the cavity 148 is providing a vacuum to the cavity 148. To provide a vacuum to the cavity 148 of the superstrate holding member 130, the superstrate chuck assembly 118 may further include a vacuum path in communication with the cavity 148. In a case that there is already a pressure differential within the assembly relative to the atmosphere around the assembly, the vacuum path can be used as a manner of reducing pressure in the cavity 148 without being coupled to a vacuum. The vacuum path may include components that together allow the cavity 148 to impart a vacuum onto the superstrate 108. The vacuum path includes a second port 168 connectable with a vacuum source (not shown) and a routing tube 170 connecting the second port 168 to the cavity 148. The second port 168 may be connected to the vacuum source via a vacuum supply tube (not shown), for example. The routing tube 170 may be a flexible tube having a first end 180 connected to the second port 168 and having a second end 182 connected to a fitting 184, e.g., a pneumatic fitting. The fitting 184 is also connected to a through hole formed through the flexible portion 134 of the superstrate holding member 130 and leading into the cavity 148. That is, by being connected to both the routing tube 170 and the through hole, the fitting 184 directs the vacuum suction downwardly into the cavity 148 via the through hole. Thus, when the second port 168 is connected to the vacuum source, a vacuum can be applied to cavity 148 in order to provide a suction force capable of coupling the area of the superstrate 108 under the cavity 148 with the flexible portion 134. Additional details for applying a vacuum to the cavity 148 can be found in U.S. Pat. No. 11,728,203.

One or more additional vacuum paths may be implemented that have the same structure as the above-discussed vacuum path, where each vacuum path is in communication with the same cavity 148 and/or communication with a corresponding additional cavity (not shown) formed in the superstrate holding member 130. The additional cavity or cavities may be disposed concentrically around the cavity 148. That is, the additional cavity or cavities may also be concentrically disposed around the central opening 132, but may be located at a greater radial distance from the inner edge 133 than the illustrated cavity 148. In an embodiment, the inner diameter of the superstrate holding member 130 may be smaller and/or the cavity 148 may have additional lands 226. For example, an additional vacuum path having the same structure as the above-described vacuum path may be located at a position diametrically opposing the above-described vacuum path. The additional cavity or vacuum cavities may be used to assist in separating the superstrate from a cured layer as part of the planarization process discussed below in more detail. In another aspect, the additional cavity or vacuum cavities allow the same superstrate chuck assembly 118 to be used with different sized superstrates.

In another embodiment, it is possible that the cavity 148 and vacuum path may be replaced with another mechanism for coupling the superstrate holding member 130 with a superstrate. For example, in place of a cavity/vacuum arrangement, an electrode that applies an electrostatic force may be included. Another option is mechanical latching where a mechanical structure on the underside of the superstrate holding member 130 is mateable (capable of making a good, close, and/or proper fit) with the superstrate.

The superstrate chuck assembly 118 may further include a rigid member 188. The rigid member 188 need not be made of a transparent material that allows for UV light to pass through. That is the rigid member 188 may be composed of an opaque material with respect to UV light. The rigid member 188 may be composed of plastic (e.g., acrylic), glass (e.g., fused silica, borosilicate), metal (e.g., aluminum, stainless steel), or ceramic (e.g., zirconia, sapphire, alumina). In an example embodiment, the rigid member 188 may be composed of the same material as the superstrate holding member 130.

FIG. 4 shows an exploded view where the rigid member 188 is shown separated from the superstrate holding member 130 and the light transmitting-member 150. As best seen in FIG. 4, the rigid member 188 may generally include a circular main body 190 defining an open central area 192. The outer circumference of the rigid member 188 may be uniform. The inner circumference of the rigid member 188 may include a step 194 that provides a receiving surface 196 for receiving the light-transmitting member 150. That is, as best seen in FIGS. 3D and 3E, the light-transmitting member 150 may be placed onto the receiving surface 196 of the step 194, thereby covering the central area 192. The light-transmitting member 150 may be secured onto the receiving surface 196, such as with an adhesive. In this manner, when the light-transmitting member 150 is placed/secured onto the receiving surface 196, the chamber 152 is defined by the underside surface of the light transmitting member, the inner surface of rigid member 188 (more particularly, the inner surface of the step 194), the upper surface of the superstrate holding member 130, and the superstrate 108.

The superstrate holding member 130 may be coupled to the underside surface of the rigid member 188 using a coupling member (not shown) such as a screw, nut/bolt, adhesive, and the like. The coupling member may preferably be located adjacent to the outer edge 191 of the rigid member 188 and adjacent the outer edge 131 of the superstrate holding member 130. When the coupling member is a screw, the coupling member preferably passes through the superstrate holding member 130 adjacent the outer edge 131 and into the rigid member 188 adjacent the outer edge 191, such as through a plurality of receiving holes 189 (FIGS. 3E, 4). When the coupling member is an adhesive, the coupling member is preferably located between the superstrate holding member 130 adjacent the outer edge 131 and the rigid member 188 adjacent the outer edge 191. In this manner, an upper surface of the superstrate holding member 130 contacts and is fixed to the underside surface of the circular main body 190 of the rigid member 188 adjacent the outer edge 131 and the outer edge 191. Additional surface area of superstrate holding member 130 may be selectively coupled to the rigid member 188 as part of the planarization process. The manner of selectively coupling the additional surface area of the superstrate holding member 130 to the rigid member 188 is discussed in more detail below.

As shown in FIGS. 3C, 3D, and 3E, all or a portion of the fluid path 154 and/or additional fluid path 155 discussed above may be contained within the rigid member 188. Similarly, all or a portion of the vacuum path and/or additional vacuum path in communication with the cavity 148 may be contained within the rigid member 188. More particularly, a portion of the first port 156, a portion of the first passage 158, the second passage 160, the first end 162, and the second end 164 of the fluid path 154 may be contained within the rigid member 188. A portion of the second port 168, among other non-illustrated pathways, of the vacuum path may be contained within the rigid member 188. However, as best shown in FIGS. 3C and 4, the routing tube 170 may be external to the rigid member 188. Thus, the rigid member 188, in addition to supporting the light-transmitting member 150 and the superstrate holding member 130, may also provide the pathway/structure for the fluid paths and vacuum paths. In an alternative embodiment, there is no routing tube 170 and the vacuum passes through a port in the rigid member 188 via a channel from the inflexible portion of the superstrate holding member 130 to the flexible portion 134 of the superstrate holding member 130 to the cavity 148.

The superstrate chuck assembly 118 may further include additional vacuum paths that allow the superstrate holding member 130 to be selectively secured to the underside surface of the rigid member 188. While the above-described vacuum flow paths communicate with the cavity 148 of the superstrate holding member 130, the additional vacuum paths that allow the superstrate holding member 130 to be selectively secured to the underside surface of the rigid member 188 are annular cavities in the rigid member 188 that are open on the underside surface of the rigid member 188. The details of these additional vacuum paths are described in U.S. Pat. No. 11,728,203. The additional vacuum paths may include components that together impart a vacuum suction force onto the upper surface of the superstrate holding member 130 to further secure the superstrate holding member 130 to the underside surface of the rigid member 188. The additional vacuum path may include a port 204 connectable with a vacuum source (not shown). The port 204 of the vacuum path 200 may be connected to the vacuum source via a vacuum tube (not shown), for example. The port 204 of the vacuum path is in communication with an annular cavity 212 having an open end facing downwardly toward the superstrate holding member 130. Thus, when the port 204 of the vacuum path is connected to the vacuum source, and the upper side surface of the superstrate holding member 130 is in contact with the underside surface of the rigid member 188, a vacuum can be applied to the annular cavity 212 to secure the superstrate holding member 130 to the rigid member 188. Further vacuum paths in communication with further annular cavities 222 and 224, each annular cavity having an open end facing downwardly toward the superstrate holding member 130. The further annular cavities may be spaced apart in a radial direction. Thus, a vacuum can be selectively applied to the annular cavities 212, 222, and 224. Details of selectively applying the vacuum to the annular cavities is provided in U.S. Pat. No. 11,728,203.

While the example embodiment of the superstrate chuck assembly 118 includes the rigid member 188 as a separate structural element from the superstrate holding member 130, in another example embodiment, the rigid member may be a single structural piece including a portion shaped like the flexible portion of the superstrate holding member and a portion shaped like the rigid member. In other words, in such an embodiment, there is no separate rigid member and instead there is a single continuous structure having a thick portion resembling the rigid member and thin portion resembling the flexible portion. Because there is not a separate rigid member ring and superstrate holding member in such an embodiment, there is also no need for any of the annular cavities or a need for any of the ports and cavities that provide a vacuum path to the annular cavities. Rather, only the fluid path(s) and possibly vacuum path(s) leading to the chamber 152 (i.e., an equivalent to fluid path 154) and possibly the vacuum path(s) leading to the flexible portion of the member (i.e., an equivalent to vacuum path in communication with the cavity 148) would be present in this embodiment.

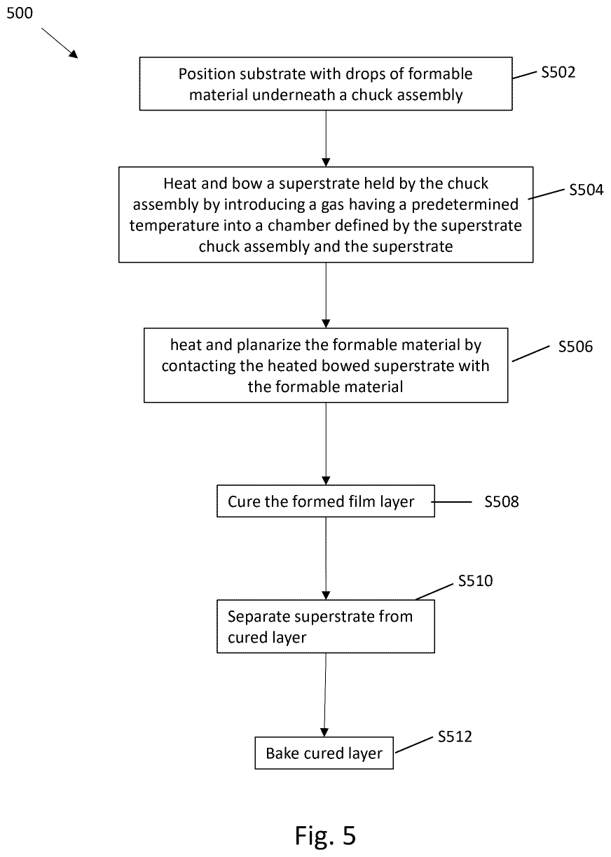

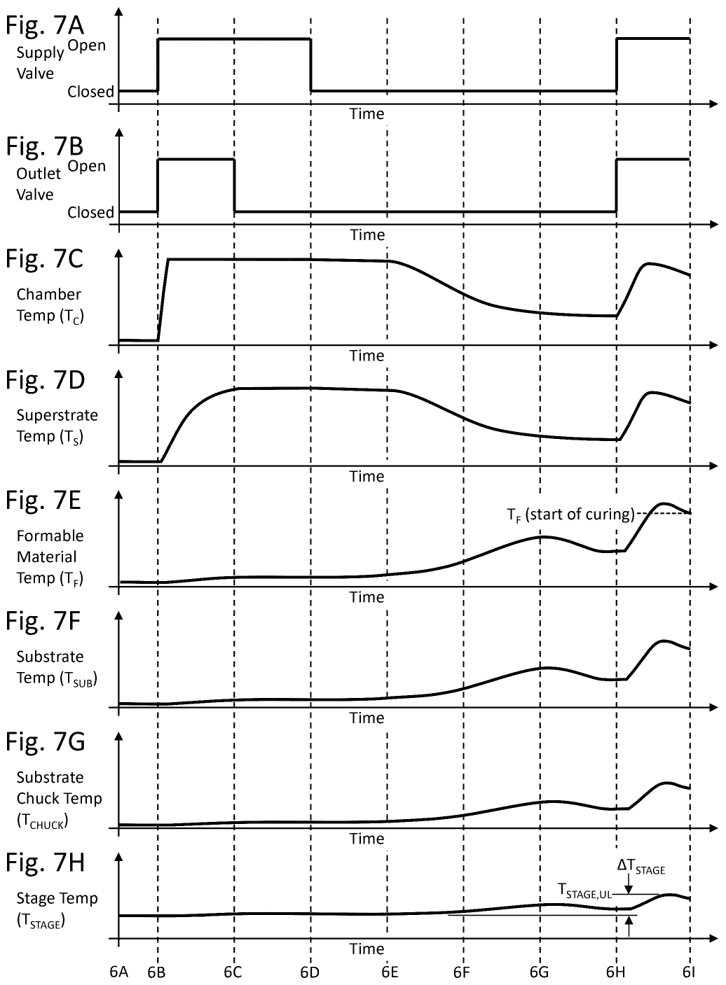

Operation of the superstrate chuck assembly 118 as part of the planarizing process will now be described with reference to FIGS. 5-6L. FIG. 5 shows a flow chart of a planarizing method 500. FIGS. 6A to 6L show cross sectional schematic views of the planarizing method 500 using the superstrate chuck assembly 118. For simplicity, the schematic representation of FIGS. 6A to 6L have omitted the cavities 212, 222, 224, among other features. FIGS. 7A-B are valve state timing charts. FIGS. 7C to 7H are timing charts indicating the temperature of various components of the planarization system 100 at different times in the planarizing method 500.

The method begins at step S502, where the substrate 102 having drops of formable material 124 dispensed thereon, is brought underneath the superstrate 108 that is coupled with the superstrate holding member 130 of the superstrate chuck assembly 118. Thus, prior to performing step S502, the drops of formable material are dispensed onto the substrate in the manner described above. This moment is shown in FIG. 6A. FIG. 6A shows a schematic cross section of the substrate 102 having dispensed formable material 124 positioned below the superstrate 108 being held by the superstrate chuck assembly 118.

Prior to performing step S502, the superstrate chuck assembly 118 is prepared by applying the vacuum suction to the cavity 148 of the superstrate holding member 130 and contacting the cavity 148 to the upper side surface of the superstrate 108, thereby coupling the superstrate 108 to the superstrate holding member 130. In a case where there are multiple vacuum cavities (e.g., 2) in the flexible portion 134 of the superstrate holding member 130, in one embodiment, less than all (e.g., only one) of the vacuum cavities will have a vacuum implemented during step S502. For example, in one embodiment, only the radially outermost cavity relative to the central opening 132 may have a vacuum imparted. However, in another embodiment, all of the vacuum cavities (e.g., 2) may have a vacuum implemented during step S502.

As shown in FIG. 6A, at the time that the substrate 102 is placed underneath the superstrate 108, the chamber 152 may not yet be pressurized with positive pressure and may not yet have any heated gas flowing into the chamber 152. In an embodiment, the gas supply valve 174 between the heater 116 and the chamber 152 may be closed (as indicated by the black triangles) and the gas outlet valve 176 may be open (as indicated by the white triangles). In another embodiment, to improve throughput, the chamber 152 may be preemptively pressurized with positive pressure by introducing the heated gas into the chamber 152 prior to the substrate 102 being positioned underneath the superstrate 108 (This may require opening gas supply valve 174 and possibly opening gas outlet valve 176). At the moment shown in FIG. 6A, the pressure P in the chamber is preferably equal to the ambient pressure, e.g., atmospheric pressure, but may also be positively pressurized or negatively pressurized which may be controlled by the gas supply valve 174 and the gas outlet valve 176. The moment show in FIG. 6A also serves at the starting, or zero point, with respect to time on the timing charts of FIGS. 7A to 7H. Each of the timing charts in FIGS. 7A to 7H show the valves state and temperature of a different aspect of the planarization system 100 over the same period. That is, the same point of the x-axis across all of the timing charts indicates the corresponding temperature of each of the components at that same moment. As shown in FIG. 6A, there is not yet any flow of heated gas into or out of the chamber 152.

FIG. 7A is a valve state chart of the gas supply valve 174 showing the open or closed states of the gas supply valve 174. FIG. 7B is a valve state chart of the gas outlet valve 176 showing the open or closed state of the gas outlet valve 176. FIG. 7C is a timing chart of the temperature Tc of the heated gas in the chamber 152. The temperature discussed herein with respect to the temperature of the gas is the average temperature across the volume of the gas in the space between the superstrate chuck assembly and 118 and the superstrate 108. FIG. 7D is a timing chart of the temperature T_{S} superstrate 108. The superstrate temperature T_{S} discussed herein with respect to the temperature of the superstrate 108 is the average temperature of the superstrate 108. FIG. 7E is a timing chart of the temperature T_{F} of the formable material (formable material 124 droplets and formable material film 144). The temperature discussed herein with respect to the temperature of the formable material 124, and the formable material film 144 is the average temperature across the volume of the formable material. FIG. 7F is the is a timing chart of the substrate temperature T_{SUB} of substrate 102. The temperature discussed herein with respect to the temperature of the substrate 102 is the average temperature across the volume of the substrate. FIG. 7G is the is a timing chart of the temperature T_{CHUCK} of substrate chuck 104. The temperature discussed herein with respect to the temperature of the substrate chuck 104 is the average temperature across the volume of the substrate chuck 104. FIG. 7H is the is a timing chart of the temperature T_{STAGE} of substrate positioning stage 106. The temperature discussed herein with respect to the temperature of the substrate positioning stage 106 is the highest measured temperature, at a particular time, measured across the entire volume of the substrate positioning stage 106. In other words, different portions of the substrate positioning stage 106 may have different temperatures at a particular time. The temperature T_{STAGE} is the temperature of the portion having the highest measured temperature.

At the moment shown in the FIG. 6A, the chamber temperature T_{C}, the superstrate temperature T_{S}, formable material temperature T_{F}, substrate material temperature T_{SUB}, the substrate chuck temperature T_{CHUCK}, and substrate positioning stage temperature T_{STAGE}, may all be approximately equal to their local ambient temperature. FIGS. 7C to 7H reflect that each of these components begin at a similar starting temperature prior to the introduction of any heated gas.

The method may then proceed to step S504, where the superstrate 108 is heated and bowed by introducing the heated gas having the predetermined temperature into the chamber defined by the superstrate chuck assembly and the superstrate (i.e., into the chamber 152). Step S504 may include several sub-steps. FIG. 6B shows a schematic cross section of the superstrate chuck assembly during a first sub-step when heated gas 172 has been introduced into the chamber 152. As shown in FIG. 6B, during this step, the heated gas 172 may be controlled to flow from the gas source 114, through the open gas supply valve 174 and the inlet fluid path 154, into the chamber 152, and out the outlet fluid path 155 and the open gas outlet valve 174. The heated gas in the gas source 114 is maintained at the predetermined temperature using the heater 116. The heated gas being introduced into the chamber 152 at a specific pressure. Because the gas is allowed to flow out of the chamber 152 via the outlet flow path 155, while the superstrate may be heated by the heated gas at this time, there is no substantial increase in pressure in the chamber such that the superstrate 108 is not bowed. The heated gas may be introduced at a flow rate of less than 10 liters per minute (LPM). That is, as shown in FIG. 6B, the pressure in the chamber 152 remains low enough that superstrate 108 is not substantially bowed. The flow of the heated gas through the outlet flow path 155 may be controlled by a gas outlet valve 176 in the outlet flow path 155. The chamber temperature T_{C} will almost immediately rise to the temperature of the heated gas supplied to the chamber 152.

FIG. 6C shows a schematic cross section of the superstrate chuck assembly 118 after the moment shown in FIG. 6B, during a second sub-step when pressure has built up in the chamber 152 sufficient to bow the superstrate 108. In the moment shown in FIG. 6C, the heated gas 172 has continued to be introduced into the chamber 152 to compensate for any leakage. At the same time, the flow of heated gas 172 is prevented from flowing of the chamber 152 via the outlet flow path 155. The flow out may be prevented by closing the gas outlet valve 176 in the outlet flow path 155. As the heated gas continues to flow into the chamber 152, the pressure in the chamber 152 continues to increase. The increase in pressure in the chamber 152 causes the superstrate 108 to bow. At the same time the superstrate 108 may move down toward the formable material 124 on the substrate 102 and/or the substrate 102 carrying the formable material 124 may be brought up toward the superstrate 108. During this time, the superstrate 108 continues to be further bowed as pressure continues to build in the chamber 152 and the superstrate 108 and continues to be heated by the heated gas.

The timing charts in FIGS. 7C to 7H show any changes in temperature that occur during the time between the moment shown in FIG. 6B, when the heated gas is first introduced, to the moment shown in FIG. 6C, after the superstrate 108 has been heated and bowed.

As shown in FIG. 7C, the heated gas has been introduced into the chamber 152 and has a constant temperature T_{C}. The temperature T_{C} of the gas may be 70° C. to 120° C. As shown in FIG. 7D, the temperature T_{S} the superstrate 108 begins to increase upon introduction of the heated gas and continues to increase throughout the time to reach the moment in FIG. 6C. In an example embodiment, the superstrate temperature T_{S} may increase by 0% to 204% from the moment of FIG. 6B to the moment in FIG. 6C, the superstrate temperature T_{S} may increase by 0° C. to 47° C. from the moment of FIG. 6B to the moment in FIG. 6C, and the superstrate temperature T_{S} may be 23° C. to 70° C. at the moment in FIG. 6C.

As shown in FIG. 7E-H, the formable material temperature T_{F}, substrate material temperature T_{SUB}, the substrate chuck temperature T_{CHUCK}, and substrate positioning stage temperature T_{STAGE}, will begin to slightly increase after the superstrate temperature T_{S} begins to increase due to convection. This is because the front side 108b gets hotter, and the proximity of the front side 108b gets closer to the formable material 124, heat will begin to transfer to the formable material 124, but relatively slowly until contact is initiated.

FIG. 6D shows a schematic cross section of the superstrate chuck assembly 118 during a third sub-step when the pressure has further built up in the chamber 152 sufficient to further bow the superstrate 108 as compared to the moment shown in FIG. 6C. That is, the pressure in the chamber 152 at the moment shown in FIG. 6D is greater than the pressure in the chamber 152 as the moment shown in FIG. 6C. Furthermore, the superstrate 108 is more significantly bowed at the moment shown in FIG. 6D as compared to the moment shown in FIG. 6C. The pressure in the chamber 152 at the moment shown in FIG. 6D may be greater than the pressure in the chamber 152 at the moment shown in FIG. 6C. In the moment shown in FIG. 8D, the heated gas has continued to be introduced into the chamber 152. At the same time, the flow of heated gas is still prevented from flowing out of the chamber 152 via the outlet flow path 155 by the closed gas outlet valve 176. As the heated gas continues to flow into the chamber 152, the pressure in the chamber 152 continues to increase. The increase in pressure in the chamber 152 causes the superstrate 108 to bow further. At the moment shown in FIG. 6D, the superstrate 108 has moved down toward the formable material 124 on the substrate 102 and/or the substrate 102 carrying the formable material 124 has been brought up toward the superstrate 108 such that the superstrate 108 is nearly touching the formable material. During this time, the superstrate 108 continues to be further bowed as pressure continues to build in the chamber 152 and the superstrate 108 continues to be heated by the heated gas. That is, as shown in FIGS. 7D to 7H, the temperature of all of the above-mentioned components continue to increase but only slightly.

The method may then proceed to step S506 where the formable material 124 is heated and planarized by being contacted with the heated bowed superstrate 108. The step S506 is shown in FIGS. 6E to 6G. FIG. 6E shows a schematic cross section of the superstrate chuck assembly 118 at the moment the heated bowed superstrate 108 has come into contact with the formable material 124 beginning to form a formable material film 144. As shown in FIG. 6E, the chamber 152 remains pressurized with the heated gas 172 previously introduced into the chamber 152. The vacuum suction continues to be applied to the cavity 148. In an embodiment, the pressure P in the chamber 152 is increased as the superstrate 108 conforms with the formable material 124 to maintain a desired curvature. The applicant has determined that it often requires more pressure to maintain a certain superstrate curvature as the un-conformed region of the superstrate decreases. As a contact area of the superstrate increases during step S506 the contact area of the superstrate begins to conform to the shape of the substrate under the contact area, while the portion of the superstrate outside the contact area is the un-conformed region in which the curvature needs to be controlled. Maintaining this curvature is important for minimizing gas trapping which can lead to non-fill defects. In an embodiment, the curvature just beyond the conformed portion (contact area) of the superstrate is controlled. In other words, the curvature of the superstrate in an annular region just outside the contact area is controlled. In an embodiment, a desired superstrate curvature profile in this annular region is controlled while formable material spreads underneath the contact area. This may require that the pressure P be maintained and/or increased during step S506. In an embodiment, the superstrate 108 is ‘flat’ (conforms to the shape of the substrate 102) after the formable material 124 has stopped spreading.

As the heated bowed superstrate 108 comes into contact with the formable material, in addition to being planarized to form the formable material film 144, heat is further transferred from the superstrate 108 to the formable material film 144. That is, because the superstrate 108 has been heated via the heated gas 172 introduced into the chamber 152, and because the formable material 124 is at a lower temperature prior to step S506, at the time of the contact of the superstrate 108 with the formable material 124 at the moment shown in FIG. 6E will continue to cause the formable material 124 to heat as it is simultaneously planarized into the formable material film 144. More specifically, the front side (bottom surface) 108b of the superstrate 108 will continue to transfer heat to the formable material 124, among the other components. After the moment shown in FIG. 6E, the chamber temperature T_{C} and the superstrate temperature T_{S} will decrease as heat is transferred from the superstrate 108 to the formable material 124 and the components below it.

FIG. 6F shows a schematic cross section of the superstrate chuck assembly 618 as it continues to move downwardly toward the substrate 102 to further form the formable material film 144. During this time the heated bowed superstrate 108 continues to heat and planarize the formable material 124 into the formable material film 144. As seen in FIG. 6F, as the superstrate 108 continues to press downwardly, the formable material film 144 of formable material 124 spreads further along the surface of the substrate 102 toward the edges. The positive pressure P is further increased or maintained so as to maintain the desired curvature in the area of the substrate that is about to conform with the formable material. As the superstrate 108 continues to press downwardly toward the substrate 102, the superstrate 108 continues to bend to maintain the desired curvature in the area of the substrate that is about to conform with the formable material. Thus, the superstrate 108 in FIG. 6F has less of an arc than in FIG. 6E such that the area of the superstrate 108 that is about to conform with the formable material maintains the desired curvature. At the same time, the flexible portion 134 also begins to flatten. The vacuum suction is still applied to the cavity 148 in FIG. 6F.

As the heated bowed superstrate 108 further comes into contact with the formable material 124, in addition to being further planarized into the formable material film 144, further heat is transferred from the superstrate 108 to the formable material film 144, and the other components mentioned above.

In an example embodiment, the chamber temperature T_{C} and the superstrate temperature T_{S} will continue to decrease as the formable material temperature T_{F}, the substrate material temperature T_{SUB}, the substrate chuck temperature T_{CHUCK}, and the substrate positioning stage temperature T_{STAGE}, continue to increase in temperature from the moment of FIG. 6E to the moment in FIG. 6F.

FIG. 6G shows a schematic cross section of the superstrate chuck assembly 118 at a point where the superstrate 108 has been fully pressed against the formable material 124 such that the formable material film 144 is fully formed. As shown in FIG. 6G, the superstrate 108 has been pressed until it is once again flat. That is, the superstrate 108 no longer has an arc or lacks a substantial arc. Similar, the flexible portion 134 of the superstrate holding member 130 is flat or lacks a substantial bend. As shown in FIG. 6G, the flow of heated gas from the gas source into the chamber 152 has been terminated. The vacuum suction is still applied to the cavity 148. With superstrate 108 fully contacting the formable material film 144, in addition to have fully planarized the formable material 124 into the formable material film 144, the formable material film 144 has been fully heated.

In an example embodiment, the chamber temperature T_{C} and the superstrate temperature T_{S} will continue to decrease as the formable material temperature T_{F}, the substrate material temperature T_{SUB}, the substrate chuck temperature T_{CHUCK}, and the substrate positioning stage temperature T_{STAGE}, continue to increase in temperature from the moment of FIG. 6F to the moment in FIG. 6G. As the contact area between the superstrate and the formable material so does the thermal conductivity and the transfer of heat from the superstrate to the rest of the system.

The predetermined temperature of the gas may be selected such that a temperature change of the formable material from the beginning of the planarization process (i.e., prior to the moment of FIG. 6A) until the start of curing in step S508 is 5° C. to 50° C. higher. The predetermined temperature of the gas may be selected such that a temperature of the formable material upon the start of the curing is 25° C. to 80° C. As noted above, the predetermined temperature of the gas may be 70° C. to 120° C. The predetermined temperature of the gas may be 10 to 250% greater than the temperature of the formable material prior to contacting the superstrate with the formable material.

The method may then proceed to step S508, where the formable material film 144 located between the superstrate 108 and the substrate 102 is cured. FIG. 6H shows a schematic cross section of the superstrate chuck assembly 118 when the superstrate 108 is first released from the superstrate holding member 130. To release the superstrate 108 the vacuum applied to the cavity 148 is terminated. More particularly, because the superstrate 108 is contacting the formable material film 144, the termination of the vacuum to the cavity 148 releases a multilayer structure comprising the superstrate 108, the formable material film 144, and the substrate 102. The gas supply valve 174 may be opened at this point in time while the multilayer structure (superstrate 108/formable material film 144/substrate 102) is beneath the superstrate chuck assembly 118. The multilayer structure is supported by the substrate chuck 104. As shown in FIG. 6H when the superstrate 108/formable material film 144/substrate 102 has been released, the outlet flow path 155 may be opened to allow the heated gas 172 to exit the chamber 152 via the outlet flow path 155. At the same time, as also shown in FIG. 6H, because the superstrate 108 is no longer held by the superstrate holding member 130, the heated gas 172 also escape out of the opening between the superstrate holding member 130 and the superstrate 108. The multilayer structure (superstrate 108/formable material film 144/substrate 102) may be held underneath superstrate chuck assembly 118 during a static spread period which may last between 0.01-360 seconds. During the static spread period the multilayer structure (superstrate 108/formable material film 144/substrate 102) may be heated by hot gas supplied by the gas supply valve 174.

As shown in FIG. 7C as soon as the heated gas is no longer introduced into the chamber 152 (i.e., at the moment shown in FIG. 6E), the temperature T_{S} of the superstrate 108 begins to drop. That is, after reaching peak temperature, with the heated gas no longer being introduced, the heat in the system begins to dissipate. The dissipation will be small prior to contact but will increase as the contact area between the superstrate and formable material increases. As seen in FIGS. 7D to 7H, each of the other components also have a temperature change after the heated gas is no longer introduced. While there is a thermal differential the heat will transfer from the hot areas of the system to cool portions of the system depending on their thermal conductivity. However, the components that are farther away from the heat source take longer for the heat to begin to dissipate and the temperature to change.

At the moment shown in FIG. 6H, where the superstrate 108/formable material film 144/substrate 102 has been released from the superstrate holding member 130, and where the heated gas previously heating the superstrate 108 is exiting the chamber 152, the temperature of all of the components may start to increase as the heated gas is reintroduced by gas supply valve 174. This continued increase in temperature is illustrated in FIGS. 7C to 7H. As shown in FIGS. 7D to 7H, the temperature of each of the components may continue to increase after the moment shown in FIG. 6H and the formable material temperature is at a target curing temperature T_{F} (start of curing) at the moment shown in step 6I (curing).

Importantly, the highest temperature of the substrate positioning stage 106 stays below an upper limit temperature 27° C. (T_{STAGE,UL}) throughout the entire process. In addition, of the substrate positioning stage temperature may stay within a substrate positioning stage temperature range (ΔT_{STAGE}) of about 5° C. That is, the peak temperature T_{STAGE} that is shown in FIG. 7H occurring between the moment of FIG. 6G and the moment of FIG. 6H, is below 27° C. if the ambient temperature is 23° C. Staying below this temperature prevents variation in the planarization performance. Other approaches for heating the formable material, such as heating the substrate with a heated substrate chuck, may cause the stage to increase in temperature by more than 5° C.

After the superstrate 108 has been released from the superstrate holding member 130 and after a static spread period, the superstrate 108/formable material film 144/substrate 102/substrate chuck 104 may be moved via the substrate positioning stage 106 to another location for curing (step S508) using the curing system. As shown in FIG. 6I, once the combination of superstrate 108/formable material film 144/substrate 102/substrate chuck 104 is present at the other location, the curing process can be performed. The curing may be performed by exposing the formable material film 144 to actinic radiation (for example UV light) through the superstrate 108. However, because the combination of superstrate 108/formable material film 144/substrate 102/substrate chuck 104 is at another location and no longer coupled to the superstrate chuck assembly 118, the UV light does not need to pass through the light-transmitting member 150 or through the superstrate holding member 130. In this embodiment, where the UV radiation does not pass through the light-transmitting member, the light-transmitting member 150 may be composed of a material that transmits greater than 80% of light having a wavelength of 400-700 nm (i.e., visible light and not UV light), e.g., glass, borosilicate, and does not need to be composed of a material that transmits UV light. After the curing is complete, the combination of superstrate 108/planarized layer 146/substrate 102/substrate chuck 104 may be brought back underneath the superstrate chuck assembly 618. After exposure to the UV radiation, the formable material film 144 of formable material is cured, thereby forming a planarized layer 146.

As noted above, FIG. 7C to 7H show the temperature of each of the components varying throughout planarization process until the moment of curing shown in FIG. 6I. Importantly, at the start time of curing, the temperature of the formable material film 144 has reached a predetermined temperature that has been determined is ideal for curing. The predetermined temperature for curing the formable material is a temperature that avoids the issues noted above, i.e., non-uniform topography is avoided or minimized in the surface of the baked layer when the temperature of the formable material is at the predetermined temperature at the time of curing which is determined based on the baking temperature. The predetermined temperature of the formable material at the start of curing may be between 25° C. to 80° C., 40° C. to 70° C., or 50° C. to 60° C. depending on the formable material and the baking temperature during step S512. The predetermined temperature of the heated gas is selected by taking into account the time and dissipation of heat that occurs during the period from when the formable material is released from the chuck assembly (along with the substrate and superstrate) to the moment that the formable material is cured. In other words, the predetermined temperature of the heated gas is selected such that the temperature of the of formable material will increase to a temporary higher temperature and then the temperature of the formable material will naturally decrease on the way to curing to ultimately arrive at the ideal curing temperature. The periods of time that the gas supply valve 174 is open is also selected based on the heat dissipation of the components in the system, experiments, heat transport calculations, and/or simulations. This ideal curing temperature may be 217 to 304% greater than the baseline temperature (for example 23° C.) of the formable material prior to any heating. The predetermined temperature of the gas may be selected such that a temperature change of the formable material 124 from prior to contacting the superstrate (i.e., prior to the moment of FIG. 6E) until curing (i.e., the moment of FIG. 6I) is 10% to 250% higher. The predetermined temperature of the gas may be selected such that a temperature change of the formable material from prior to contacting the superstrate until being cured is 25° C. to 80° C. higher. The predetermined temperature of the gas may be selected such that a temperature of the formable material at the time of curing is 50° C. to 60° C.

In another embodiment, the curing step may be performed after the combination of superstrate 108/planarized layer 146/substrate 102/substrate chuck 104 is released from the superstrate holding member, but without moving the combination of superstrate 108/planarized layer 146/substrate 102/substrate chuck 104 to another location. That is, the curing can occur at the same location as the superstrate chuck assembly 118, but with the combination of superstrate 108/planarized layer 146/substrate 102/substrate chuck 104 at a distance below the superstrate chuck assembly 118. In this case, the radiation source 126 may emit, for example, actinic radiation (for example UV radiation) that is directed through the light-transmitting member 150 and through the superstrate 108, each of which allow the UV radiation to pass through. In an embodiment the superstrate holding member 130 may be transparent to the UV radiation. In the embodiment where the UV radiation passes through the light-transmitting member, the light-transmitting member 150 may be composed of a material that transmits greater than 80% of light having a wavelength of 310-700 nm (i.e., UV light and visible light), e.g., sapphire, fused silica).

In the case where the curing occurs at the same location as the chuck assembly, the temperatures of the upper side of the superstrate, bottom side of the substrate, formable material, etc. at the time of curing is the same as provided above when the curing occurs at a separate curing location. However, because there is less time for heat to dissipate after the formable material is planarized into the formable material film 144, the temperature of the heated gas may be lower than the case where the curing happens at the same location. For example the heated gas may have a temperature that is 5% lower when the curing occurs at the same location compared to when the curing occurs at a different location.

The method may then proceed to step S510, where the superstrate 108 is separated from the planarized layer 146. FIG. 6J shows a schematic cross section of the superstrate chuck assembly 118 above the combination of superstrate 108/planarized layer 146/substrate 102, at a moment when a separation initiator 110 has been extended upwardly to initiate a separation front between the superstrate 108 and the planarized layer 146. The substrate chuck 104 may include the separation initiator 110. The separation initiator 110 may be a pushpin in one example embodiment. The separation initiator 110 may reside within a passageway extending through the substrate chuck 104. The separation initiator 110 is configured to move upwardly. The separation initiator 110 may extended through a hole or notch in the substrate 102 and contact the underside of the superstrate 108. As shown in FIG. 6J the separation initiator 110 may come into contact with the underside of the superstrate 108 at the outer edge of the superstate 108. The application of upward force on the underside of the superstrate 108 by the separation initiator causes a small portion of the superstrate 108 to release form the planarized layer 146. This initial separation at the edge is also an initiation of a separation front between the superstate 108 and the planarized layer 146.

Next, with the separation front having been initiated, the superstrate 108 may be recoupled with the superstrate holding member 130. FIG. 6K shows schematic cross section of the superstrate chuck assembly 118 and the combination of superstrate 108/planarized layer 146/substrate 102, at a moment when the superstrate 108 has been recoupled with the superstrate holding member 130. As shown in FIG. 8K, the vacuum is once again applied to the cavity 148 so that the upper surface of the superstrate 108 is coupled with the superstrate holding member 130. After the superstrate 108 is once again coupled with the superstrate holding member 130, the separation front may be propagated until complete separation of the superstrate 108 form the planarized layer 146 is achieved. The separation front may be propagated through lifting and/or rotating the superstrate chuck assembly 118 until the complete separation is achieved. A detailed method of separating the superstrate 108 from the planarized layer 146 is described in U.S. Pat. App. Pub. No. US 2023/0095200, published Mar. 30, 2023, which is hereby incorporated by reference it its entirety. During this period the gas outlet valve 176 may be open and the gas supply valve 174 may be closed.

FIG. 6L shows a moment once the separation of step S510 has been competed just after superstrate 108 has been released from the planarized layer 146. As shown in FIG. 6L after completing the separation, the superstrate chuck assembly 118 retains the superstrate 108 and the substrate 102 retains the planarized layer 146. The planarization method 500 can be then be started again for another substrate by returning to the orientation shown in FIG. 6A. As noted above, the planarization method 500 may be repeated many times, on the order of tens of thousands. When it is desirable to remove the superstrate 108 from the superstrate chuck assembly 118 (for example after a predetermined number of planarization processes have been completed or if some other indicator suggests that the superstrate should be replaced), the vacuum applied to the vacuum cavity 148 may be released.

After the superstrate 108 is removed from the cured planarized layer, the substrate 108 with a cured planarized layer is removed from the substrate chuck 104. The substrate with the cured planarized layer may then be baked during a baking step S512. The baking step S512 may be performed in a baking module that is a part of the planarization system 100 or in a separate baking tool. The baking step S512 is performed at a baking temperature and a baking soak time. The baking temperature in step S512 may be selected based on subsequent processing steps. The baking step S512 will have a tendency to increase the degree of polymerization of the cured planarized layer. The baking steps S512 can also have an impact on the planarization performance as the baked layer shrinks relative to the cured planarized layer. The applicant has found that the planarization performance after baking can be improved if the temperature at the start of curing is selected based on the baking temperature. The applicant has found that it is helpful to store a cure temperature-baking temperature look up table that includes a relationship between the baking temperature and the curing temperature of the formable material at the start of curing. This look up table may be generated based on experimental performance in which a variety of films are formed and baked at different temperatures. This look up table may then be used to select the gas temperature of the heated gas supplied by the heater 116. The processor 140 may receive the planned baking temperature and send instructions to the heater 116 based on the cure temperature-baking temperature look up table.

Embodiments as described herein can be used to keep a thickness change between a baked layer and a pre-cured layer or between a baked layer and a cured layer of a photocurable composition closer to 0% when comparing photocuring temperature at higher than ambient temperature as compared to photocuring at ambient temperature. A moderate photocuring temperature, as compared to too low or too high of a photocuring temperature, may allow a thickness change of 0% to be achieved. Better dimensional stability helps to make processes more robust and repeatable from substrate to substrate and from production lot to production lot. The inventors have found that for each material there is photocure thickness change that is dependent upon the photocuring temperature and there is baking thickness change that is dependent upon the baking temperature. The inventors have found that it is possible to select that one of the photocure thickness change and baking thickness change is positive while the other is negative so as to give an optimal thickness change as close to zero as possible.

Further modifications and alternative embodiments of various aspects will be apparent to those skilled in the art in view of this description. Accordingly, this description is to be construed as illustrative only. It is to be understood that the forms shown and described herein are to be taken as examples of embodiments. Elements and materials may be substituted for those illustrated and described herein, parts and processes may be reversed, and certain features may be utilized independently, all as would be apparent to one skilled in the art after having the benefit of this description.

What is claimed is:

1. A planarizing method, comprising:
heating and bowing a superstrate held by a superstrate chuck by introducing a gas having a predetermined temperature into a chamber defined by the superstrate chuck and the superstrate; and
heating and planarizing a formable material by contacting the heated bowed superstrate with the formable material,
wherein the predetermined temperature of the gas is greater than a temperature of the formable material prior to contacting the heated bowed superstrate with the formable material.

2. The planarizing method of claim 1, wherein the predetermined temperature of the gas is selected such that a temperature change of the formable material from prior to contacting the superstrate until start of curing is 10 to 250%.

3. The planarizing method of claim 1, wherein the predetermined temperature of the gas is selected such that a temperature change of the formable material from prior to contacting the superstrate until start of curing is between 2° C. to 60° C.

4. The planarizing method of claim 1, wherein the predetermined temperature of the gas is selected such that a temperature of the formable material at start of curing is 25° C. to 80° C.

5. The planarizing method of claim 1, wherein the predetermined temperature of the gas is 70°° C. to 120° C.

6. The planarizing method of claim 1,
wherein the heating of the superstrate includes heating a back of the superstrate,
wherein heat from the back of the superstrate transfers to a front of the superstrate, and
wherein the front of the superstrate faces the formable material.

7. The planarizing method of claim 6, wherein the predetermined temperature of the gas is selected such that the temperature of the superstrate is 50° C. to 70° C. when the superstrate contacts the formable material.

8. The planarizing method of claim 1, further comprising:
releasing the superstrate from the superstrate chuck;
further heating the superstrate with the gas or with a second gas having a second predetermined temperature while the formable material is spreading between the superstrate and the substrate; and
curing the formable material,
wherein the predetermined temperature of the gas or the second predetermined temperature of the second gas is selected such that the temperature of the formable material is 25° C. to 80° C. at start of the curing.

9. The planarizing method of claim 1, wherein bowing the superstrate by introducing the gas into the chamber comprises pressurizing the chamber with the heated gas.

10. The planarizing method of claim 9, wherein a pressure in the chamber is increased as the superstrate is heated.

11. The planarizing method of claim 9, wherein pressurizing the chamber with the gas comprises preventing the gas from exiting the chamber after being introduced into the chamber.

12. The planarizing method of claim 1, wherein prior to bowing the superstrate, the superstrate is initially heated by introducing the gas into the chamber while maintaining a pressure in the chamber that is insufficient to bow the superstrate.

13. The planarizing method of claim 12, wherein the pressure in the chamber is maintained by venting the gas out of the chamber at the same time that the gas is introduced into the chamber.

14. The planarizing method of claim 13, wherein the gas is introduced into the chamber via an inlet port and the gas is vented out of the chamber via an exit port.

15. The planarizing method of claim 1, wherein the introducing of the gas into the chamber is terminated prior to releasing the superstrate from the superstrate chuck.

16. The planarizing method of claim 15, wherein the gas is released from the chamber when the superstate is released from the superstrate chuck.

17. The planarizing method of claim 1, wherein the gas is a member selected from the group consisting of clean dry air, nitrogen, helium, neon, and argon.

18. The planarizing method of claim 1,
wherein the formable material is on a substrate carried by a stage,
wherein the stage reaches a maximum temperature during the planarizing method,
wherein the stage has a minimum temperature during the planarizing method, and
wherein a difference between the maximum temperature and the minimum temperature is less than 5° C.

19. A planarization system, comprising:
a superstrate chuck configured to hold a superstrate;
a chamber at least partially defined by the superstrate chuck; and
a gas source in communication with the chamber and configured to introduce a gas having a predetermined temperature into the chamber,
wherein the predetermined temperature of the gas is 70° C. to 120° C.

20. A method of manufacturing an article, comprising:
dispensing a formable material on a substrate;
heating and bowing a superstrate held by a superstrate chuck by introducing a gas having a predetermined temperature into a chamber defined by the superstrate chuck and the superstrate;
heating and planarizing the formable material by contacting the heated bowed superstrate with the formable material, thereby forming a film of the formable material between the superstrate and the substrate;
curing the film of the formable material to form a cured layer between the superstrate and the substrate;
separating the superstrate from the cured layer to form a planarized layer;
baking the planarized layer on the substrate to form a baked planarized layer; and
processing the baked planarized layer on the substrate to make the article,
wherein the predetermined temperature of the gas is greater than a temperature of the formable material prior to contacting the heated bowed superstrate with the formable material.
